(19) United States
(12) Patent Application Publication
(10) Pub. No.: US 2022/0060001 A1
(43) Pub. Date: Feb. 24, 2022

(54) BUSBAR ADAPTER

(71) Applicant: Klaus Bruchmann GmbH, Weißkirchen an der Traun (AT)

(72) Inventors: Klaus Ewald Karl Bruchmann, Coburg (DE); Thomas Berger, Oberstreu (DE)

(21) Appl. No.: 17/299,412

(22) PCT Filed: Dec. 4, 2018
(86) PCT No.: PCT/EP2018/083501

§ 371 Date: Jul. 9, 2021

(51) Int. Cl. H02B 1/21; G01R 15/18

(52) U.S. Cl. CPC H02B 1/21; G01R 15/181

(57) ABSTRACT

The present invention relates to a busbar adapter for connection to a polyphase busbar system, wherein the busbar adapter comprises a top covering element and a bottom covering element, contact devices and contact lines. The busbar adapter also comprises a current measuring device which is designed such that current measurement can be carried out for each phase of the busbar adapter in the busbar adapter.

The present invention relates to a busbar adapter for connection to a polyphase or multi-pole busbar system, in particular to a three-phase busbar system having three busbars. Such busbar adapters are suitable in particular for fastening and connecting electrical devices, for example installation devices, to electrical busbar systems.

A system of this type is known for example from DE 195 15 923 C2 or EP 2 975 708 A1.

An object of the present invention is to improve such a busbar adapter further in terms of user-friendliness and taking into account the desired applications.

This object is achieved by a busbar adapter according to claim 1; Claims 2 to 15 relate to particularly advantageous embodiments of such a busbar adapter, and claim 16 relates to a bottom covering element for such a busbar adapter.

The busbar adapter according to the present invention comprises a housing, the housing comprising at least one top covering element and one bottom covering element. The top covering element is designed such that electrical devices, for example installation devices, can be fastened, the bottom covering element being designed such that an electrical connection to the busbars of the busbar system can be produced.

The busbar adapter comprises at least two contact devices, each for connection to one of the busbars of the busbar system. As explained above, the present invention relates in particular to a busbar adapter for a three-phase busbar system, also referred to as a triple-pole busbar system, in which case the busbar system has three busbars, so that the busbar adapter also comprises three contact devices, one contact device per busbar.

The busbar adapter also comprises at least two contact lines for an electrical connection to an electrical device which can be fastened to the busbar adapter, in particular to the top covering element, the contact line being connected electrically to a contact device. The contact devices are arranged on or in the bottom covering element.

In a three-phase or triple-pole system, the busbar adapter of course comprises three contact devices and three contact lines, so that an electrical connection to each of the busbars can be produced.

According to the invention, the busbar adapter additionally comprises a current measuring device which is designed such that current measurement can be carried out for each phase or for each pole of the busbar adapter in the busbar adapter.

This has the advantage that a current measurement, in particular a current measurement which takes into account each individual phase (each pole), can be carried out already in the busbar adapter, at a central point, that is, before and independently of the connected devices.

For the user or operator, this has the advantage that all relevant information about the connected system, can be obtained at this central point, in particular conclusions can be drawn directly about the operation of the system, the power consumption and changes during operation which are important for the operation or monitoring of the system.

In particular, current measuring devices no longer have to be provided at the individual devices, in particular installation devices, and therefore such a busbar adapter allows an increased flexibility when using the electrical devices, because in principle all devices, irrespective of whether they allow current measurement or not, can be connected to the busbar adapter, without having to forgo the useful information with regard to the overall system.

The current measuring device can be a substantially integral current measuring device which can perform a current measurement for each phase of the busbar adapter, but the current measuring device preferably consists of multiple sub-units or components or current measuring devices. Preferably, a dedicated current measuring device is used per phase.

In this case, there are particularly advantageous ways and possibilities of accommodating such a current measuring device in the busbar adapter in a particularly preferred manner, in particular in a particularly space-saving and effective manner, as described in detail below.

The current measuring device or the multiple components or units or current devices is/are preferably arranged on or in the bottom covering element. This has advantages in particular during production, since the contact device are typically and preferably likewise provided in the bottom covering element, so that the contact lines run from there, and the current measuring devices can be provided even at this point. In particular in the case of a two-part form of the housing with a top covering element and a bottom covering element, or else in the case of multi-part housings, which comprise an intermediate covering element, for example, this construction results in a simplification of the overall structure and therefore in more cost-effective production and prevents operating errors.

A particularly preferred possibility of implementing a current measuring device is the provision of at least one Rogowski coil. Preferably, one Rogowski coil per phase or pole is used as the current measuring device.

Such Rogowski coils are preferably implemented as components which have a plate shape, preferably a rectangular plate shape, in particular a square plate shape, so that the dimensions can be kept very small. Preferred Rogowski coils in the form of such a plate element are substantially square, with a plate thickness of 1 to 4 millimetres, for example 1.6 or 3.2 millimetres, and an edge length of 10 to 25 millimetres, preferably 16 or 22 millimetres.

Such components can therefore be installed in the busbar adapter, in particular the bottom covering element of a busbar adapter, in a particularly space-saving manner, so that the height of the busbar adapter does not have to be increased.

According to one embodiment, the Rogowski coils or the corresponding components are installed in the busbar adapter, in particular in the bottom covering element of the busbar adapter, such that they extend parallel or substantially parallel to a plane which is formed by the busbars of the busbar system. This direction is also referred to below as the horizontal direction. Since the components which the Rogowski coils contain have a relatively small thickness, in particular 1 to 4 millimetres as mentioned above, in particular the height of the busbar adapter can be kept small thereby.

In a particularly preferred embodiment, however, the Rogowski coils or the components of the Rogowski coils are arranged and fastened in the busbar adapter such that a plane in which the coil windings of the Rogowski coils lie runs perpendicular or substantially perpendicular to a plane which is formed by the busbars of the busbar system. This installation direction is also referred to below as the vertical direction.

As mentioned above, such Rogowski coils are preferably implemented as plate-shaped components, the plane in which the coil winding of the Rogowski coils lies corresponding to the plane of the plate-shaped component.

In this connection, it should be noted that the plane which is formed by the busbars of the busbar system is referred to as the x-y plane or horizontal plane, whereas a direction perpendicular or normal hereto is referred to as the vertical direction, in this application also as the z application.

A busbar adapter according to the invention extends over all the bars of the busbar adapter in a direction (x direction) parallel to said horizontal plane or x-y plane and perpendicular to a longitudinal extent of each of the busbars (y direction).

This extent of the busbar adapter transversely to the longitudinal extent of the busbars (y direction) defines a longitudinal direction or longitudinal axis of the busbar adapter, which is oriented in the x direction.

At its ends (in the longitudinal direction), the busbar adapter and/or the bottom covering element and/or the top covering element have end faces which delimit the respective elements in this longitudinal direction, along the x axis.

Particularly preferably, corresponding receiving pockets, preferably slot-shaped receiving pockets, are provided in the busbar adapter, in particular in the bottom covering element of the busbar adapter, into each of which receiving pockets one current measuring device, in particular the aforementioned Rogowski coils, can be inserted. This results in a simple and thus cost-effective assembly.

It is particularly preferred that these receiving pockets, which are in particular slot-shaped, to receive the Rogowski coils or corresponding components, extend at least partially into a foot element of the bottom covering element, which are provided for fastening the busbar adapter to the busbars and which in particular also comprise the contact devices or parts of the contact devices.

In this case, the spatial conditions of a busbar adapter are used in a particularly preferred manner; in particular, the overall dimensions and in particular the height of the busbar adapter, in particular of the bottom covering element, can remain small in comparison with busbar adapters which comprise no current measuring device at all. Furthermore, it is particularly simple, thanks to the connection conditions, to route the contact lines of the busbar adapter through the Rogowski coil or the corresponding components, which comprise a feedthrough opening for the contact lines. Such an arrangement, which provides a vertical or substantially vertical or a perpendicular or substantially perpendicular arrangement of the Rogowski coils or the corresponding components in the bottom covering element, with receiving pockets being provided at the same time in the bottom covering element and extending at least partially into a foot element of the bottom covering element, therefore implements in a particularly advantageous, combinational manner both the advantages of the preferred arrangement of the current measuring device and the contact holder in terms of the assembly and the accuracy of the measurements, while the overall dimensions, in particular the height, can be kept small at the same time.

Such an arrangement also ensures that not only the height but also the amount of construction material can be kept small, thus achieving a plastic-saving and thus cost-effective flat design.

In a further preferred embodiment, the busbar adapter also comprises an electronic evaluation unit, which can be connected to current measuring devices, in particular to the preferred Rogowski elements.

Preferably, the electronic evaluation unit comprises a housing, which can be fastened to an end face of the busbar adapter, in particular to an end face of the bottom covering element of the busbar adapter, the housing of the evaluation unit comprising one or more hook elements, which can be inserted in associated openings in an end face of the busbar adapter, in particular in associated openings in the end face of the bottom cover of the busbar adapter. Such an implementation of an electronic evaluation unit obtains and supports the above-described plastic-saving and thus cost-effective flat design in a particularly advantageous manner; in particular, the evaluation unit and the housing do not extend beyond the height of the busbar adapter, preferably not even beyond the height of the bottom covering element of the busbar adapter.

Fastening by means of hook elements which can be hooked into associated openings in the busbar adapter in particular has the advantage that, on the one hand, assembly can be carried out very simply and therefore cost-effectively, and on the other hand, it is also possible to remove the evaluation unit relatively simply, if it is not or no longer needed at a later point in time or for a certain application. Recycling is also simplified, since individual components can be separated quickly and easily.

Particularly preferably, the hook elements and the associated openings are designed such that the electronic evaluation unit can be hooked into the bottom covering element, and then the electronic evaluation unit is held and/or locked in its operating position by attaching the top covering element, and therefore no additional holding or locking elements are necessary.

According to a further embodiment, the contact lines are stripped of insulation in the region of the Rogowski coils. This has advantages in particular for contact lines having relatively large line cross sections, for example for line cross sections of 10 mm² or 16 mm². This can also keep the overall height small without affecting the efficiency and while maintaining galvanic isolation.

Preferably, the current measuring device or the current measuring devices, in particular the Rogowski coils, is/are connected to the electronic evaluation unit by means of electrical lines; these lines preferably likewise run completely within the bottom covering element.

In a preferred embodiment, the electronic evaluation unit also comprises at least one RJ socket (“Registered Jack socket”), or similar connections, for connection to a bus link, in order to conduct the evaluations particularly advantageously.

It is also possible, in another preferred embodiment, to provide the busbar adapter and in particular the electronic evaluation unit with devices or modules which allow a WLAN connection or a Bluetooth connection or another connection for data transfer.

The invention also relates to a bottom covering element for a busbar adapter as described above, the bottom element comprising at least two foot elements for fastening the bottom covering elements to busbars. As mentioned above, these are generally three-phase or triple-pole systems, and therefore the bottom covering element comprises three foot elements.

Such a bottom covering element comprises at least two receiving pockets, in a three-phase or triple-pole design three receiving pockets, which are preferably slot-shaped and can each receive one current measuring device, in particular the aforementioned Rogowski coils. As described, these receiving pockets preferably run in a plane which runs perpendicular or substantially perpendicular to a plane which is formed by the busbars, each of the receiving pockets extending at least partially into a foot element as described above.

These and further features and advantages of the present invention are detailed using the drawings below, which show particular embodiments.

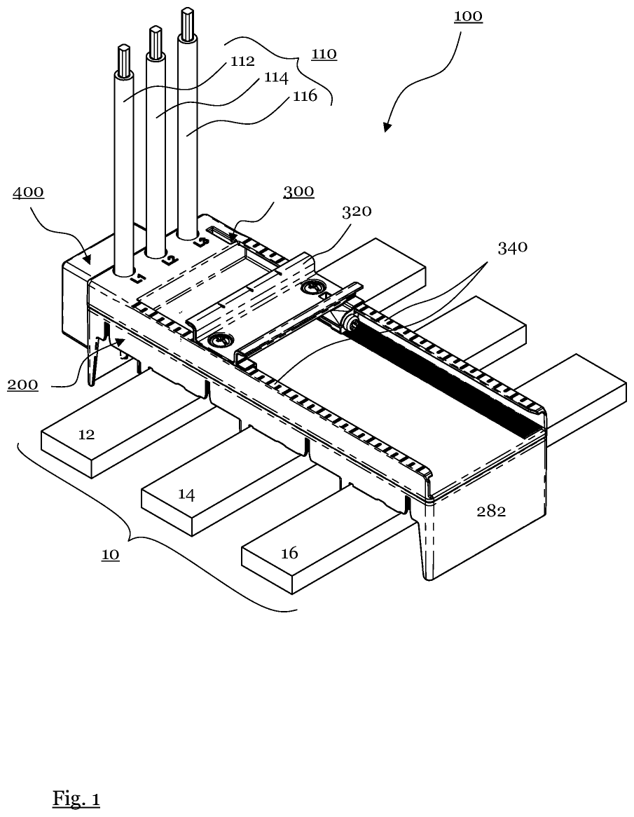

FIG. 1 shows a perspective view of a busbar adapter according to the present invention;

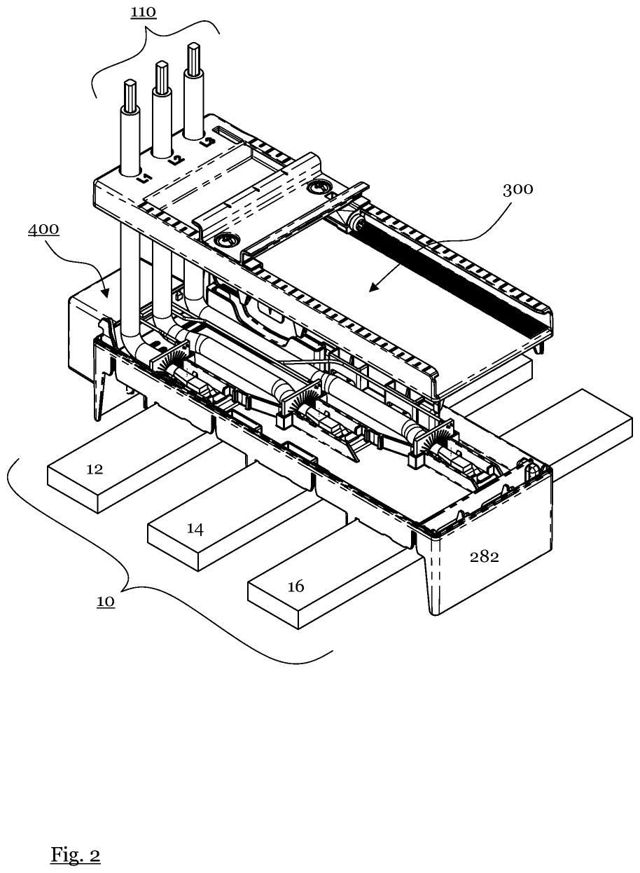

FIG. 2 shows the embodiment of the busbar adapter according to the invention shown in FIG. 1 in a partially exploded diagram;

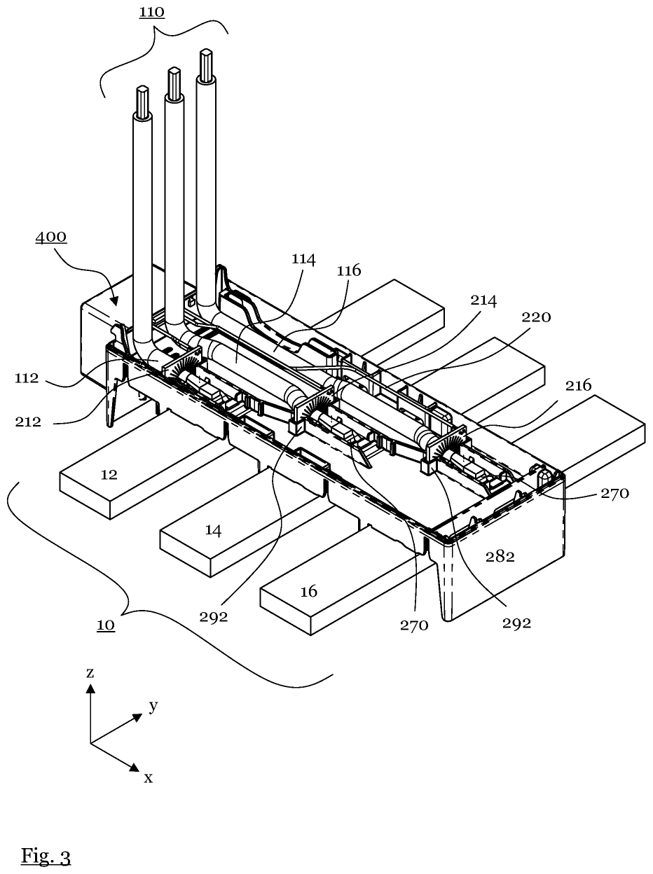

FIG. 3 shows the embodiment of the busbar adapter shown in FIGS. 1 and 2, but without the top covering element;

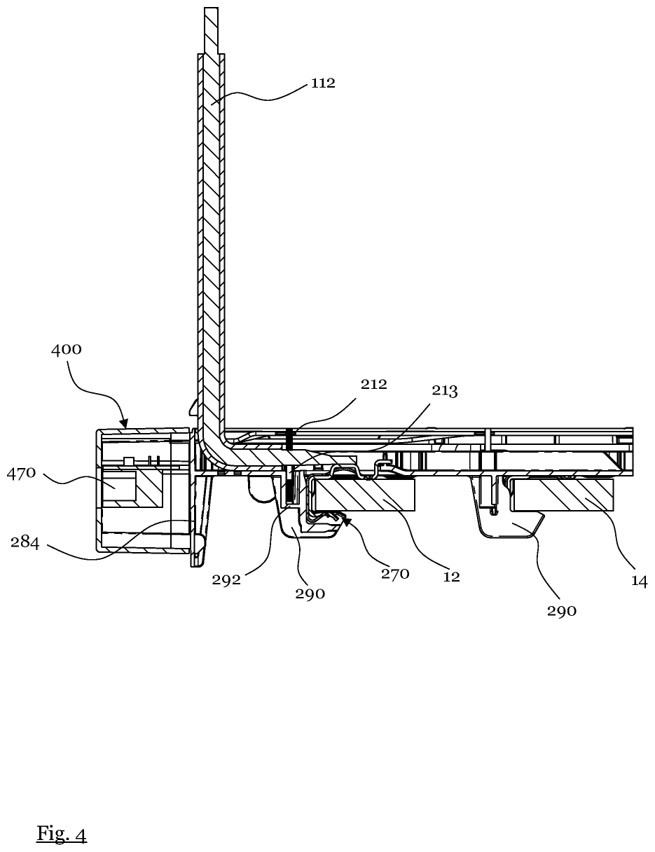

FIG. 4 shows a partial cross-sectional view of some elements of the embodiment of a busbar adapter according to the invention shown in FIGS. 1 to 3;

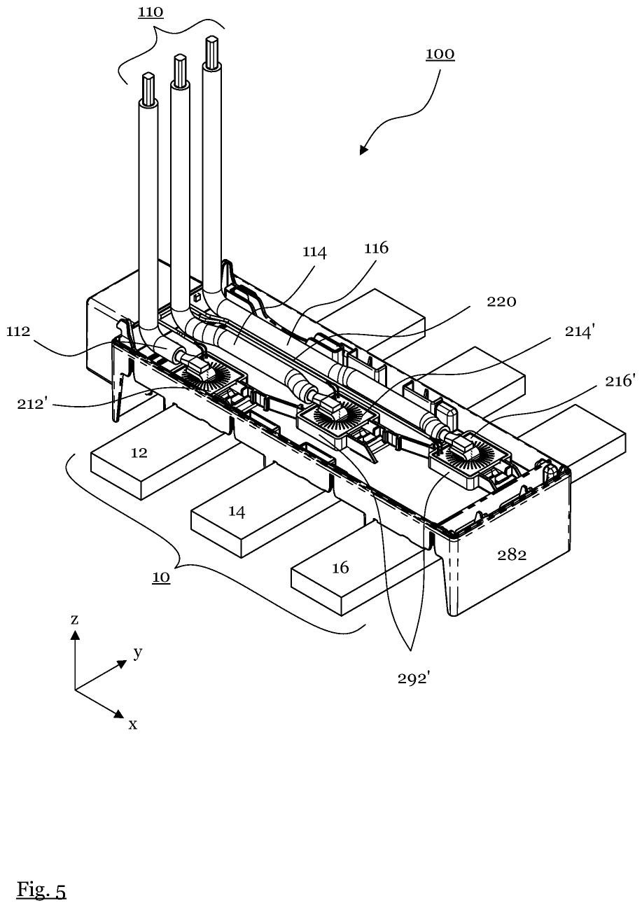

FIG. 5 shows a further embodiment of a busbar adapter according to the invention, but without an associated top covering element;

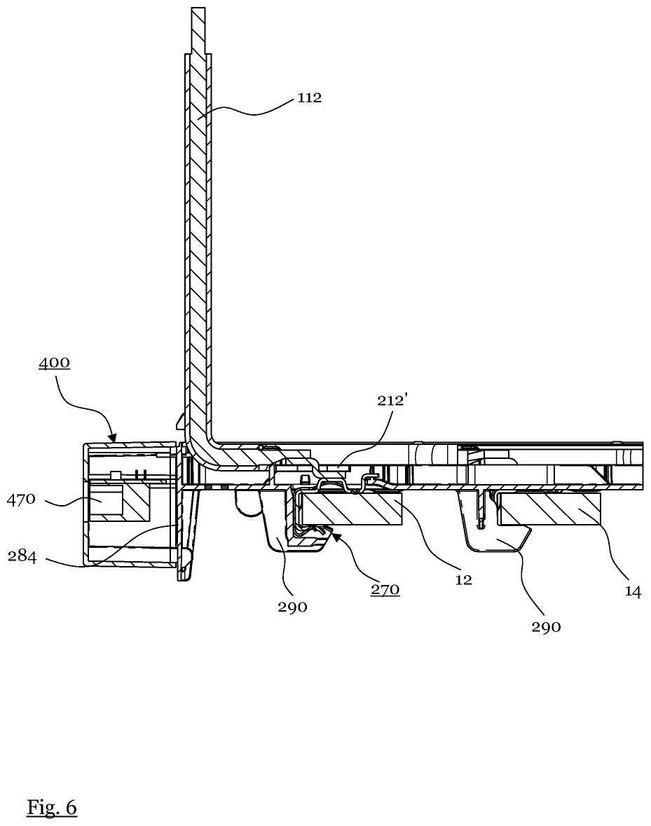

FIG. 6 shows a partial cross-sectional view of some elements of the embodiment of a busbar adapter according to the invention shown in FIG. 5;

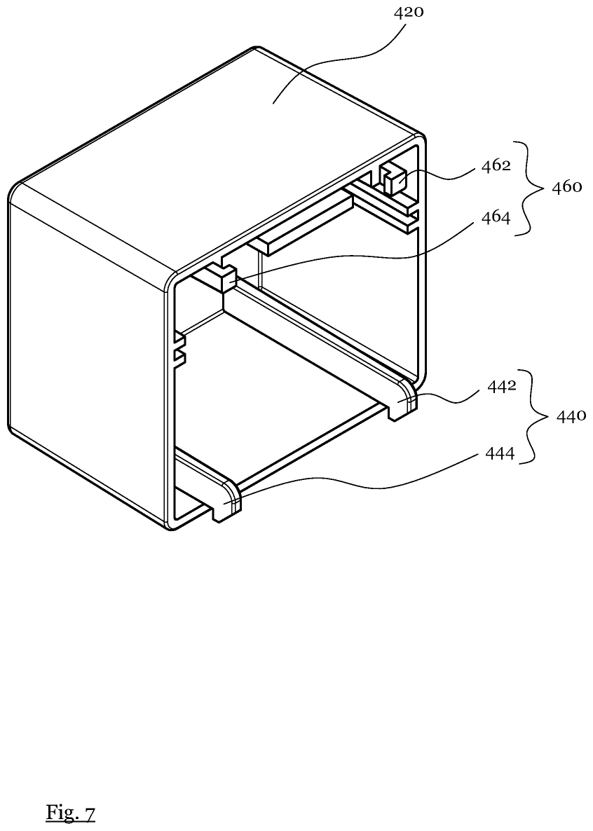

FIG. 7 shows a perspective view of a housing of an electronic evaluation unit;

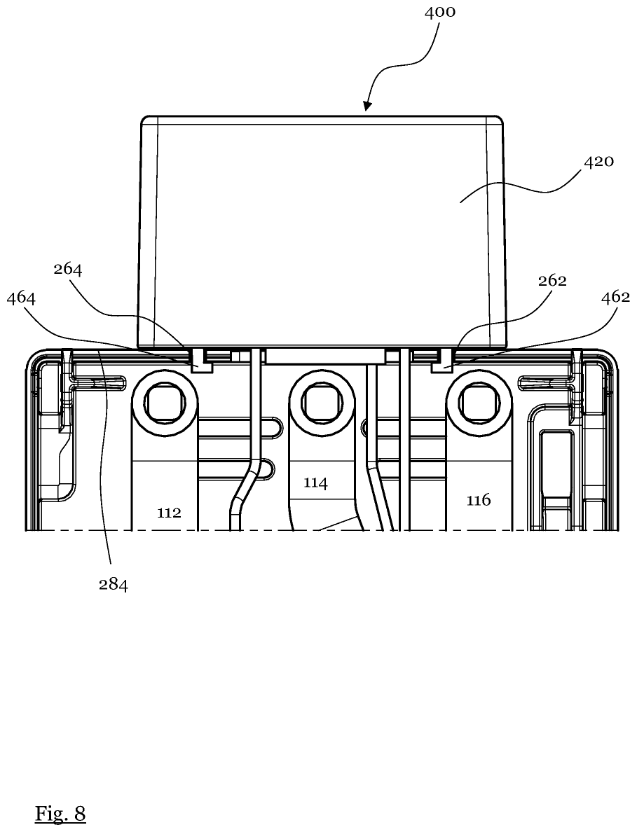

FIG. 8 shows a partially cut-away view of a portion of a busbar adapter according to the invention;

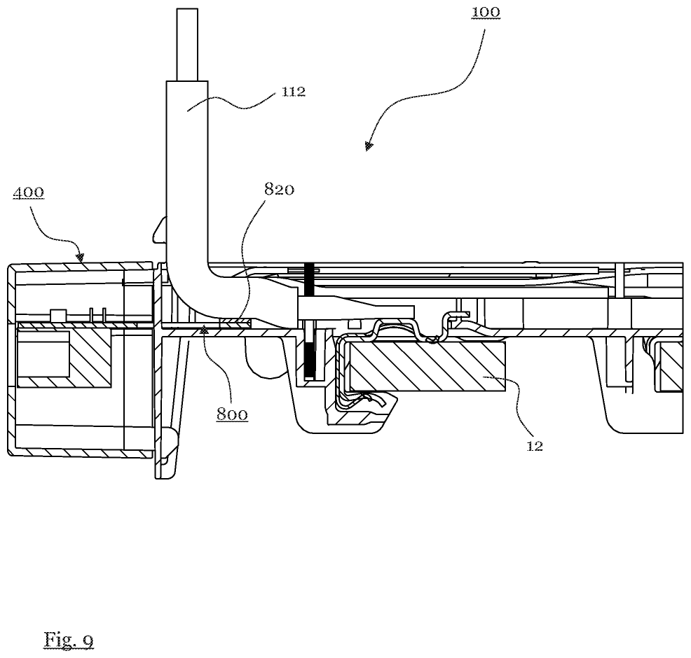

FIG. 9 shows a partial cross-sectional view of some elements of a further embodiment of a busbar adapter according to the invention;

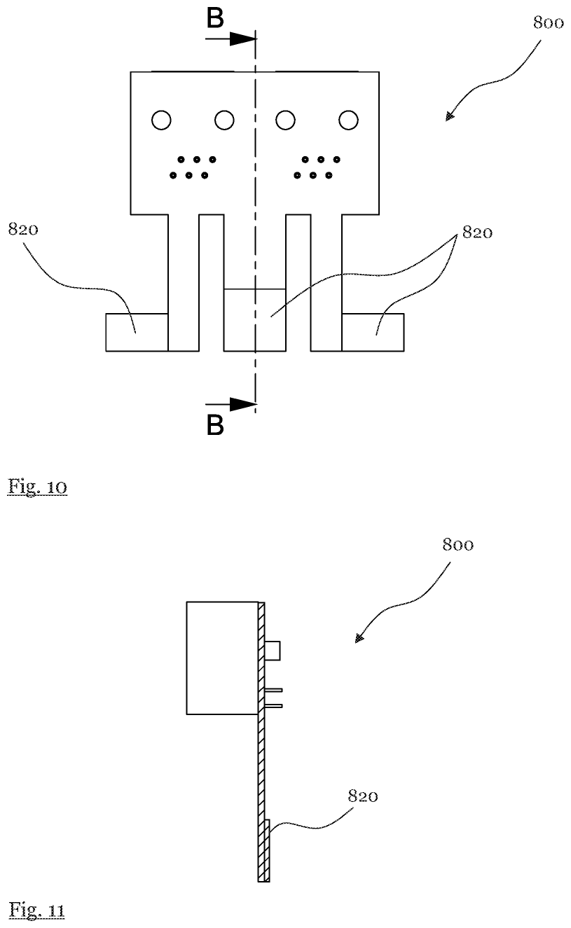

FIG. 10 shows a view from above of a measuring element, which operates by means of a capacitive coupling and can be used in an embodiment as shown for example in FIG. 9; and

FIG. 11 shows a cross section through the measuring element shown in FIG. 10, along line B-B.

FIG. 1 shows a first embodiment of a busbar adapter 100 according to the invention for connection to a triple-pole or three-phase busbar system 10, which comprises three busbars 12, 14, 16, which are partially shown in FIG. 1.

The busbar adapter 100 comprises a bottom covering element 200 and a top covering element 300, which are connected to each other in an operating position, as shown in FIG. 1.

In this embodiment, the top covering element 300 comprises holding or fastening flanges 340 on which, in different positions, one or more carrying rails 320 for fastening electrical devices can be fastened.

The bottom covering element 200 comprises in total three feet and three contact devices, by means of which the bottom covering element 200 and thus the busbar adapter 100 can be fastened to the busbars 12, 14, 16 and brought into electrical contact with same. In this perspective view, the feet and contact elements are difficult or impossible to see but are shown in more detail in particular in FIG. 4.

The bottom covering element has two end faces, only one of which, specifically the end face 282, is shown in FIG. 1 owing to the perspective diagram, while the other end face (284; see FIG. 4) is arranged opposite, so that the busbars 12, 14, 16 run between these end faces 282, 284 when the busbar adapter 100 is arranged in its position and fastened on the busbar system 10.

The embodiment of the busbar adapter 100 shown in FIG. 1 also comprises an electronic evaluation unit 400, which is attached and fastened to one end face (284; see FIG. 4) of the bottom covering element 200.

The busbar adapter 100 comprises in total three contact lines 112, 114, 116, referred to jointly with reference sign 110, which are connected to the contact devices (270; see in particular FIG. 4) and produce the electrical connection to an electrical device which can be arranged and fastened on the busbar adapter 100, in particular on the carrying rail 320, which, as described above, can be adjusted in position substantially in a region between the two end faces (282, 284; see FIG. 4).

FIG. 2 shows the embodiment shown in FIG. 1 in a partially exploded diagram, in which the top covering element 300 is shown shifted partially vertically upwards to make the bottom covering element 200 visible.

FIG. 3 shows the embodiment shown in FIGS. 1 and 2, in which the top covering element has been completely removed.

FIG. 3 shows the course of the contact lines 112, 114, 116 and at least part of the contact devices 270; see also FIG. 4.

The busbar adapter 100 also comprises a current measuring device, which in this embodiment is implemented overall by Rogowski coils 212, 214, 216. As can be seen easily in FIG. 3, the Rogowski coils 212, 214, 216 in this embodiment are arranged vertically, that is, substantially parallel to the end faces 282 (284; see FIG. 4) or else perpendicular to an x-y plane which is formed by the busbars of the busbar system. The Rogowski coils or the plate-shaped components therefore extend in a y-z direction, in which the plane of the end faces 282 (284; see FIG. 4) of the bottom covering element also extends.

The plate-shaped Rogowski coils 212, 214, 216 are arranged in slot-shaped receiving pockets 292, which likewise extend vertically or in the y-z direction and partially project into an associated foot of the bottom covering element 200, which can be seen better in FIG. 4.

The Rogowski coils 212, 214, 216 or the corresponding components have a substantially centrally arranged opening, through which the contact lines 112, 114, 116 are routed, so that the current measurement can be carried out for each phase.

The Rogowski coils 212, 214, 216 are connected to the electronic evaluation unit 400 by means of lines 220, so that the results of the current measurement can be received, processed and/or forwarded there, for example via a bus system.

FIG. 4 shows a partial cross-sectional view through some components of the embodiment shown in FIGS. 1 to 3. FIG. 4 again illustrates the arrangement of the Rogowski coils, in particular the Rogowski coil 212, which has a central opening 213, through which the contact line 112 is routed. As can likewise be seen clearly in FIG. 4, the contact line 112 is stripped of insulation in the region of the Rogowski coil 212.

FIG. 4 also shows the slot-shaped receiving pocket 292 for receiving the Rogowski coil 212, the receiving pocket 292 extending partially into the region of the foot 290. The Rogowski coil 212 or the corresponding component also therefore extends partially, in the embodiment shown here over approximately half its edge length, into the region of the foot 290 of the bottom covering element 200.

As can therefore be seen easily in FIG. 4, the Rogowski coils 212 (214, 216; see FIG. 3) are therefore arranged in a particularly space-saving and effective manner, so that the height of the bottom covering element does not have to be increased in comparison with busbar adapters without current measurement. At the same time, the Rogowski coils do not project beyond an upper edge of the bottom covering element 200, that is, beyond an edge of the bottom covering element 200 which is oriented towards the top covering element.

As can also be seen in FIG. 4, the electronic evaluation unit 400 is arranged on an end face 284 of the bottom covering element 200, and the dimensions are selected such that the height of the busbar adapter is not increased at all by the evaluation unit.

FIG. 5 shows a further embodiment of a busbar adapter 100 according to the invention, which is very similar to the embodiment shown in FIGS. 1 to 4, and therefore reference is also made to the description of FIGS. 1 to 4 to avoid repetitions.

In the embodiment shown in FIG. 5, however, the Rogowski coils 212′, 214′, 216′ are arranged differently, specifically parallel to an x-y plane which is spanned by the busbars 12, 14, 16 of the busbar system 10. The Rogowski coils 212′, 214′, 216′ therefore extend in an x-y direction.

In this embodiment too, receiving pockets 292′ are provided, which are arranged in the bottom covering element 200, while the contact lines 112, 114, 116 are likewise routed through an opening in the Rogowski coils 212′, 214′, 216′, the current measurement being carried out at least partially in the region of the contact devices in such an embodiment.

FIG. 6 shows a partial cross-sectional diagram of some elements of the embodiment shown in FIG. 5, similar to FIG. 4 with regard to the first embodiment, and therefore reference is made to the description of FIG. 4 to avoid repetitions.

As can be seen in FIG. 6, the Rogowski coils 212′ (the other Rogowski coils are not shown in this partial cross-sectional drawing) are arranged such that they extend in a plane parallel to the x-y plane which is spanned by the busbars 12, 14, 16.

FIG. 7 shows an embodiment of a housing 420 of the electronic evaluation unit as can be used in the two aforementioned embodiments.

As can be seen clearly in FIG. 7, the housing 420 comprises lower hook elements 442, 444, provided overall with reference sign 440, and upper hook elements 462, 464, provided overall with reference sign 460. These hook elements 440, 460 are inserted into the corresponding openings in the bottom covering element, so that the electronic evaluation unit or the housing 420 can be connected securely to the busbar adapter, in particular the bottom covering element. The lower hook elements 440 are bent downwards, that is, in the z direction, while the upper hook elements 460 are bent inwards, that is, in the y direction, so that secure positioning is ensured in all directions.

FIG. 8 shows a partial view from above of an embodiment of a busbar adapter according to the invention in the region in which the electronic evaluation unit 400 is arranged.

As can be seen in FIG. 8, the upper hook elements 462 and 464 lie in associated openings 262, 264 which are provided in the end wall 284 of the bottom covering element. The openings 262 and 264 are open at the top, so that the hook elements 462, 464 can be inserted easily.

As soon as the top covering element (not shown in FIG. 8) is placed onto the bottom covering element 200, the hook elements 462 and 464 are held and locked in the associated openings 262, 264, so that the evaluation unit 400 is fastened securely to the busbar adapter.

FIG. 9 shows a partial cross-sectional view of some elements of a further embodiment of a busbar adapter according to the invention. This embodiment shown in FIG. 9 is very similar to the embodiment shown in FIG. 4, and therefore reference is made in particular to the description of the embodiment shown in FIGS. 3 and 4 to avoid repetitions.

In contrast to the embodiment shown in FIGS. 3 and 4, the embodiment of the busbar adapter 100 according to the invention shown in FIG. 9 additionally comprises a measuring element which can carry out measurements for each of the phases by means of a capacitive coupling.

As can be seen in FIG. 9, this embodiment of the busbar adapter 100 comprises a measuring element 800, part of which extends in the busbar adapter 100 itself and part of which extends into the evaluation unit 400. To this end, the measuring element 800 comprises multiple capacitive elements 820, which are arranged such that, in the operating position, they are directly adjacent to the contact lines (112, 114, 116; see for example FIG. 3; only one of the contact lines, specifically the contact line 112, can be seen in FIG. 9).

FIG. 10 shows a view from above of the measuring element 800, and it can be seen very easily in FIG. 10 that the measuring element 800 comprises three capacitive elements 820 in total, for each of the three phases.

The capacitive element 820 which can be seen in FIG. 9 corresponds to the capacitive element 820 shown on the left in FIG. 10.

Finally, FIG. 11 shows a cross section through a capacitive module 800 along line B-B in FIG. 10, in which the capacitive element 820 is likewise easily visible. This capacitive element allows further and more detailed monitoring of the operating state of the overall system.

The features of the invention disclosed in the description, claims and drawings can be essential to the implementation both individually and in any combination.

1. A busbar adapter for connection to a polyphase busbar system (10), preferably to a three-phase busbar system (10) having three busbars (12, 14, 16),
wherein a housing of the busbar adapter comprises a top covering element (300) and a bottom covering element (200), and wherein the top covering element (300) is designed to fasten electrical devices thereto, and wherein the bottom covering element (200) is designed to produce an electrical connection to the busbars (12, 14, 16) of the busbar system (10),
wherein the busbar adapter (100) comprises at least two contact devices (270), each for connection to one busbar (12, 14, 16), and at least two contact lines (112, 114, 116) for an electrical connection to an electrical device, wherein each contact line (112, 114, 116) is electrically connected to one contact device (270), and wherein the contact devices (270) are arranged on the bottom covering element (200),
wherein the busbar adapter (100) comprises a current measuring device (212, 214, 216, 212′, 214′, 216′) which is designed such that current measurement can be carried out for each phase of the busbar adapter in the busbar adapter.

2. The busbar adapter according to claim 1, characterised in that the current measuring device (212, 214, 216, 212′, 214′, 216′) is arranged on or in the bottom covering element (200).

3. The busbar adapter according to claim 1, characterised in that the current measuring device comprises at least one Rogowski coil (212, 214, 216, 212′, 214′, 216′), preferably one Rogowski coil per phase.

4. The busbar adapter according to claim 3, characterised in that at least one Rogowski coil (212′, 214′, 216′), preferably all the Rogowski coils, are arranged and fastened in the busbar adapter (100) such that a plane in which the coil windings of the Rogowski coil (212′, 214′, 216′) lie lies parallel or substantially parallel to a plane which is formed by the busbars (12, 14, 16) of the busbar system (10).

5. The busbar adapter according to claim 3, characterised in that at least one Rogowski coil (212, 214, 216), preferably all the Rogowski coils, are arranged and fastened in the busbar adapter (100) such that a plane in which the coil windings of the Rogowski coil (212, 214, 216) lie runs perpendicular or substantially perpendicular to a plane which is formed by the busbars (12, 14, 16) of the busbar system (100).

6. The busbar adapter according to claim 1, characterised in that the bottom covering element (200) comprises at least two receiving pockets (292), preferably slot-shaped receiving pockets (292), each for one current measuring device, in particular one Rogowski coil (212, 214, 216), wherein the receiving pockets (292) each define a plane which lies perpendicular or substantially perpendicular to a plane which is formed by the busbars (12, 14, 16) of the busbar system (100).

7. The busbar adapter according to claim 6, characterised in that the bottom covering element (200) comprises at least two foot elements (290) for fastening the busbar adapter (100) to the busbars (12, 14, 16), wherein each of the receiving pockets (292) for a current measuring device, in particular a Rogowski coil (212, 214, 216), extends at least partially into a foot element (290).

8. The busbar adapter according to claim 6, characterised in that the receiving pockets (290) are in the form of blind holes.

9. The busbar adapter according to claim 3, characterised in that the Rogowski coils (212, 214, 216, 212′, 214′, 216′) are implemented as a component which has a plate shape, preferably a rectangular plate shape, in particular a square plate shape.

10. The busbar adapter according to claim 1, characterised in that it comprises an electronic evaluation unit (400).

11. The busbar adapter according to claim 10, characterised in that the electronic evaluation unit (400) comprises a housing (420) which can be fastened to an end face of the busbar adapter (100), in particular to an end face (284) of the bottom covering element (200) of the busbar adapter (100), wherein the housing (420) preferably comprises one or more hook elements (442, 444, 440; 462, 464, 460), which can be inserted into associated openings in an end face (284) of the busbar adapter, in particular associated openings in an end face (284) of the bottom covering element (200) of the busbar adapter (100).

12. The busbar adapter according to claim 10, characterised in that the electronic evaluation unit (400) can be fastened to an end face (284) of the bottom covering element (200) of the busbar adapter, wherein the busbar adapter is designed such that the electronic evaluation unit (400) is locked by the top covering element (300) on the end face (284) of the bottom covering element when the bottom covering element (200) and the top covering element (300) are in their operating position.

13. The busbar adapter according to claim 3, characterised in that the contact lines (112, 114, 116, 100) are stripped of insulation in the region of the Rogowski coils (212, 214, 216, 212′, 214′, 216′).

14. The busbar adapter according to claim 10, characterised in that each of the current measuring devices, in particular each of the Rogowski coils (212, 214, 216, 212′, 214′, 216′), are connected to the electronic evaluation unit (400) by means of electrical lines (220).

15. The busbar adapter according to claim 10, characterised in that the electronic evaluation unit (400) comprises at least one RJ socket (470) for connection to a bus link.

16. A bottom covering element (200) for a busbar adapter (100) according to any one of the preceding claims, characterised in that the bottom covering element (200) comprises at least two foot elements (290) for fastening the bottom covering element (200) to busbars (12, 14, 16; 10), wherein the bottom covering element (200) comprises at least two receiving pockets (292, 292′), preferably slot-shaped receiving pockets (292), each for one current measuring device, in particular a Rogowski coil, wherein the receiving pockets (292) each define a plane which runs perpendicular or substantially perpendicular to a plane which is formed by the busbars (12, 14, 16; 10), and wherein each of the receiving pockets (292) extends at least partially into a foot element (290).
